(19) United States
(12) Patent Application Publication
(10) Pub. No.: US 2010/0059476 A1
(43) Pub. Date: Mar. 11, 2010

(54) METHOD FOR MANUFACTURING A MAGNETIC STORAGE MEDIUM

(75) Inventors: Tadashi Yamamoto, Tsukuba-shi (JP); Hiroyuki Yamakawa, Chigasaki-shi (JP)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(73) Assignee: ULVAC, INC., Kanagawa (JP)

(21) Appl. No.: 12/515,668

(22) PCT Filed: Nov. 20, 2007
(86) PCT No.: PCT/JP2007/072421

§ 371 Date: May 20, 2009

(30) Foreign Application Priority Data
Nov. 22, 2006 (JP) 2006-315556

(51) Int. Cl. C23C 14/34; C23F 1/02

(52) U.S. Cl. 216/22; 204/192.2

(57) ABSTRACT

A method for manufacturing a magnetic storage medium that improves the flatness of the magnetic storage medium. A storage layer is formed on a substrate. Next, a resist mask is formed above the storage layer. Then, a pit is formed in the storage layer using the resist mask. Afterwards, a non-magnetic layer having a thickness that is in accordance with the depth of the pit is formed in the pit and above the resist mask. Subsequently, the resist mask and the non-magnetic layer formed above the resist mask are removed from the storage layer.

### TECHNICAL FIELD

The present invention relates to a method for manufacturing a magnetic storage medium.

### BACKGROUND ART

Generally, the planar recording density of a magnetic storage medium such as a magnetic disk is increasing since magnetic grains forming a recording layer have been drastically reduced in size. As the planar recording density becomes higher, heat fluctuation resulting from miniaturized crystallization of a recording layer causes magnetic inversion and narrowed tracks. This causes crosstalk with adjacent tracks and enlarges the recording magnetic field in a magnetic head, which thereby may result in the writing of data to an adjacent track.

Accordingly, for example, patent document 1 suggests a disk-read type magnetic recording medium that improves the planar recording medium. The magnetic recording medium forms a predetermined pattern of pits and lands in a recording layer and fills a non-magnetic material into the pits of the pit-land pattern.

For example, patent document 2 discloses a processing technique for forming a pit-land pattern through a dry etching process, such as reactive ion etching used in microfabrication of semiconductor elements. A film-formation technique such as sputtering employed in the microfabrication of semiconductor elements may also be performed to fill non-magnetic material into the pits of a recording layer.

The distance between a magnetic disk and a magnetic head is controlled to be on the order of nanometers (e.g., 10 nm or less). When steps are included in the surface of a magnetic recording medium, this destabilizes the levitation of the magnetic head. As a result, writing failures and reading failures may occur.

By using the film-formation technique such as sputtering as described above to fill the pits with non-magnetic material, films of the non-magnetic material are formed in the pits and on the lands. As a result, the surface of the magnetic recording medium has a pit-land shape that conforms to the pit-land pattern of the recording layer. Thus, in the disk-read type magnetic recording medium, the surface of lands on a recording layer and the surface of non-magnetic material filled in pits are flattened so that they become flush with the surface of a magnetic disk. For example, patent document 3 discloses a flattening technique using a polishing technology such as chemical mechanical polishing (CMP), which is employed in the microfabrication of semiconductor elements.

As mentioned above, the distance between a magnetic disk and a magnetic head is controlled to be on the order of nanometers. Thus, in the surface of the magnetic disk, steps (for example, steps produced between the surface of a land formed on a recording layer and the surface of non-magnetic material) must be several nanometers (e.g., 3 nm) or less.

However, when employing the CMP technique, it is difficult to remove slurry from the recording layer and out of the pits. Thus, much time and cost is required to wash off the slurry.

### Patent Document 1: Japanese Laid-Open Patent Publication No. 9-97419

### Patent Document 2: Japanese Laid-Open Patent Publication No. 2000-322710

### Patent Document 2: Japanese Laid-Open Patent Publication No. 2003-16622

### DISCLOSURE OF THE INVENTION

The present invention provides a method for manufacturing a magnetic storage medium that improves the flatness of the magnetic storage medium.

A first aspect of the present invention is a method for manufacturing a magnetic storage medium. The method includes a magnetic layer formation step of forming a magnetic layer on a substrate, a mask formation step of forming a resist mask above the magnetic layer, a pit formation step of forming a pit in the magnetic layer using the resist mask, a non-magnetic layer formation step of forming a non-magnetic layer, which has a thickness that is in accordance with the depth of the pit, in the pit and above the resist mask, and a resist removal step of removing the non-magnetic layer deposited above the resist mask together with the resist mask from the magnetic layer.

### BRIEF DESCRIPTION OF THE DRAWINGS

FIG. 1 is a cross-sectional view of a magnetic storage medium according to the present invention;

FIG. 2 is a schematic cross-sectional view illustrating a magnetic layer formation step in a method for manufacturing a magnetic storage medium in a first embodiment;

FIG. 3 is a schematic cross-sectional diagram illustrating a mask formation step and a pit formation step in the method for manufacturing a magnetic storage medium in the first embodiment;

FIG. 4 is a schematic cross-sectional diagram illustrating a non-magnetic layer formation step in the method for manufacturing a magnetic storage medium in the first embodiment;

FIG. 5 is a schematic cross-sectional diagram illustrating a resist removal step in the method for manufacturing a magnetic storage medium in the first embodiment;

FIG. 6 is a schematic cross-sectional diagram illustrating a magnetic layer formation step in the method for manufacturing a magnetic storage medium in a second embodiment;

FIG. 7 is a schematic cross-sectional diagram illustrating a resist removal step in the method for manufacturing a magnetic storage medium in the second embodiment;

FIG. 8 is a schematic cross-sectional diagram illustrating a sacrificial layer removal step in the method for manufacturing a magnetic storage medium in the second embodiment;

FIG. 9 is a schematic cross-sectional diagram illustrating the sacrificial layer removal step in the method for manufacturing a magnetic storage medium in the second embodiment;

FIG. 10 is a schematic diagram showing a emission intensity spectrum of light obtained when etching the magnetic layer and a emission intensity spectrum of light obtained when etching the sacrificial layer;

FIG. 11 is a schematic diagram showing changes as time elapses in the emission intensity of the lights for 325 nm and 375 nm in the sacrificial layer removal step;

FIG. 12 is a schematic cross-sectional diagram illustrating a method for manufacturing a magnetic storage medium in a modification; and

FIG. 13 is a schematic cross-sectional diagram illustrating a method for manufacturing a magnetic storage medium in a further modification.

### BEST MODE FOR CARRYING OUT THE INVENTION

### First Embodiment

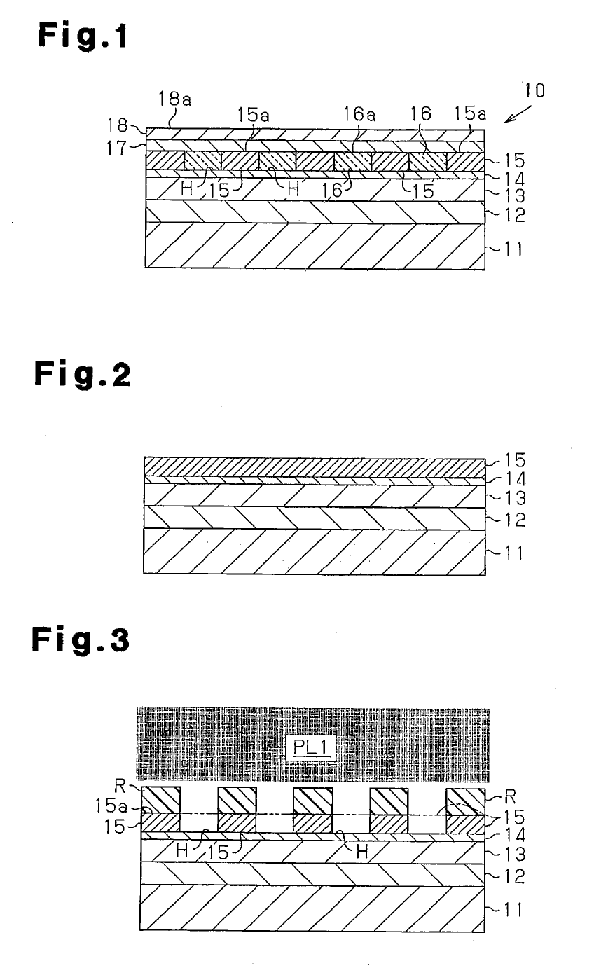

A first embodiment of a magnetic recording medium according to the present invention will now be discussed with reference to the drawings. First, a magnetic storage medium manufactured through the present invention will be discussed. The magnetic recording medium is, for example, a magnetic disk 10 of a vertical magnetic storage type. FIG. 1 is a schematic cross-sectional view showing the magnetic disk 10.

As shown in FIG. 1, the magnetic disk 10 includes a substrate 11, an underlying layer 12 laminated on the upper surface of the substrate 11, a soft magnetic layer 13, an orientation layer 14, storage layers 15 serving as magnetic layers, non-magnetic layers 16, a protection layer 17, and a lubricant layer 18.

For example, a crystallized glass substrate, a reinforced glass substrate, a silicon substrate, or a non-magnetic substrate such as an aluminum alloy substrate may be employed as the substrate 11.

The underlying layer 12 is a buffer layer for smoothing the surface roughness of the substrate 11 and ensures adhesion of the substrate 11 with the soft magnetic layer 13. Further, the underlying layer 12, which also functions as a seed layer that determines the crystalline orientation of an upper layer, determines the crystalline orientation of the laminated soft magnetic layer 13. For example, an amorphous or microcrystal alloy including one element selected from the group consisting of Ta, Ti, W, and Cr or a laminated film of such an amorphous and microcrystal alloy may be employed as the underlying layer 12.

The soft magnetic layer 13 is a magnetic layer that enhances vertical orientation of the storage layers 15. For example, an amorphous or microcrystal alloy including one element selected from the group consisting of Fe, Co, Ni, Al, Si, Ta, Ti, Zr, Hf, V, Nb, C, and B or a laminated film of such alloys may be employed as the soft magnetic layer 13.

The orientation layer 14 is a layer for determining the crystalline orientation of the storage layers 15. For example, a single-layer structure of Ru, Ta, Pt, MgO, etc. or a multilayer structure in which a Ru layer or a Ta layer is laminated on an MgO layer may be employed as the orientation layer 14.

The storage layers 15 serve as separate data tracks used for storage and reproduction. The separate storage layers 15 each include an upper surface (storage surface 15a), which is parallel to the upper surface of the substrate 11. Each storage layer 15 includes a data region and servo region that differ from each other in shape and size. In FIG. 1, to ease illustration, data regions formed in equal pitch widths are partially shown. To increase the planar storage density, it is preferred that each storage layer 15 include a magnetization facilitating axis extending in a thicknesswise direction (vertical magnetization film).

At least one ferromagnetic material selected from the group consisting of a Co, Ni, Fe, or Co alloy may be used as the magnetic material of the storage layers 15.

Alternatively, for example, a granular film including SiO₂, Al₂O₃, and Ta₂O₃ and mainly composed of CoCr, CoPt, CoCrPt, etc. may be used as the magnetic material of the storage layers 15. The layer structure of the storage layers 15 may be a single layer structure or a multilayer structure, which includes two ferromagnetic layers and a non-magnetic layer arranged between the two ferromagnetic layers. That is, each storage layer 15 may be formed so as to couple the magnetization of each of the two ferromagnetic layers in an antiferromagnetic manner via a non-magnetic coupling layer arranged between the ferromagnetic layers.

The non-magnetic layers 16 fill the gaps (pits H) between the storage layers 15 so as to magnetically separate the storage layers 15. Each non-magnetic layer 16 has an upper surface (non-magnetic surface 16a), which is a flat surface continuous with the storage surface 15a of the adjacent storage layer 15. For example, the largest step produced between the non-magnetic surfaces 16a and the storage surfaces 15a is 3 nm or less. Further, SiO₂, Al₂O₃, Ta₂O₃, and MgF₂ may be used as the non-magnetic material of the non-magnetic layers 16.

The protection layer 17 protects the storage layers 15 and the non-magnetic layers 16 and has a thickness of, for example, 0.5 to 15 nm. For example, diamond-like carbon (DLC), carbon nitride aluminum oxide, or zirconium oxide may be used for the protection layer 17.

The lubricant layer 18 is for sliding the magnetic head in the planar direction when the magnetic disk 10 comes into contact with the magnetic head to prevent the magnetic disk 10 and magnetic head from being damaged. To keep flat the common surface formed by the storage surfaces 15a and the non-magnetic surfaces 16a flat, the lubricant layer 18 has a surface 18a which is further flattened. For example, a known organic lubricant such as a perfluoro-polyether compound may be used for the lubricant layer 18.

A method for manufacturing the magnetic disk 10 will now be discussed. FIGS. 2 to 5 are diagrams illustrating the processes that are performed in the method for manufacturing the magnetic disk 10.

Referring to FIG. 3, after forming the storage layers 15, resist masks R are formed on the storage layers 15 in correspondence with the data tracks (mask formation step). The resist masks R are formed by performing EB lithography in which electron beam (EB) positive resist is spin-coated onto the storage layers 15. Alternatively, the resist masks R may be formed by performing nano-imprinting to directly apply nano-imprinted polymer. Further, an ArF laser using ArF resist or a KrF laser using KrF resist may be used.

After forming the resist mask R, the substrate 11 is entirely exposed to reactive plasma PL1 to form a patters (pits H) on the storage layers 15 using the resist masks R (pit formation step). A halogen gas, such as Cl₂, BCl₃, HBr, C₄F₈, or CF₄, a gas mixture of the halogen gas and Ar or N₂, or a gas mixture of NH₃ and CO may be used as etching gas.

After etching the storage layers 15, the substrate 11 may entirely be exposed to hydrogen plasma including active hydrogen species (hydrogen ions, hydrogen radicals), H₂O plasma, and the plasma of a gas mixture composed of at least one of Ar and N₂ with hydrogen or water. This reduces the halogen active species collected on the pattern of the storage layers 15 and the exposed orientation layer 14 with the hydrogen active species. Thus, corrosion (after corrosion) of the pattern of the storage layers 15 is avoided, and adhesion of the orientation layer 14 and the non-magnetic layers 16 is ensured.

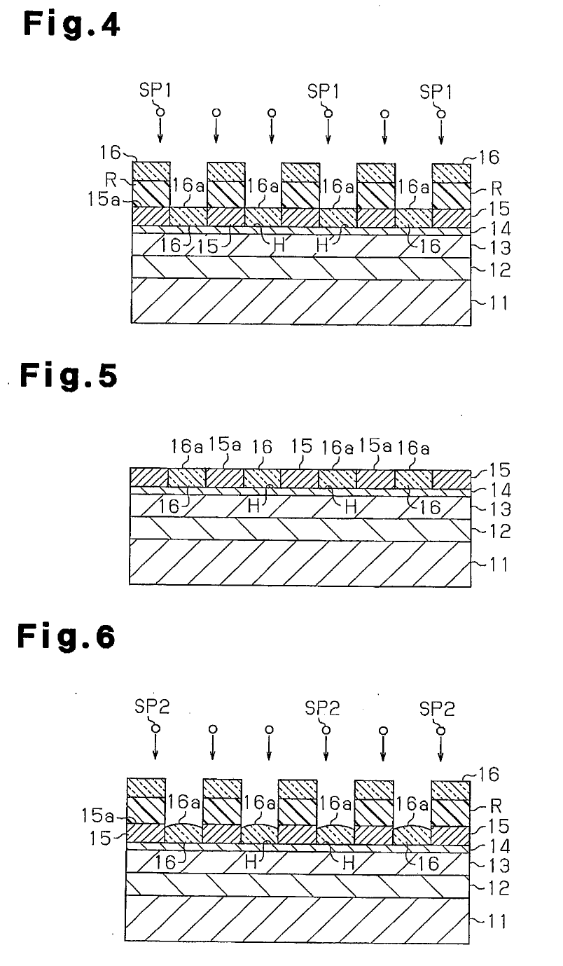

Referring to FIG. 4, after the formation of the storage layers 15, sputter grains SP1, which are a non-magnetic material, are deposited on the entire substrate 11. That is, the non-magnetic layers 16 are formed in the pits H and on the resist masks R.

During formation of the non-magnetic layers 16, anisotropic sputtering is performed on the entire substrate 11 so that the striking direction of the sputter grains SP1 is substantially the same as the normal direction of the substrate 11. Anisotropic sputtering refers to sputtering in which sputter grains travel only in a generally normal direction of a substrate. This brings the striking direction of the sputter grains SP1 close to the normal direction of the substrate 11. Thus, the sputter grains SP1 are uniformly deposited generally throughout the entire width of each pit H. At a timing in which the thickness of the non-magnetic layers 16 deposited in the pits H becomes substantially the same as the thickness of the storage layers 15 (depth of the pits H), the formation of the non-magnetic layer 16 ends. This flattens the non-magnetic surfaces 16a and the storage surfaces 15a to the same level.

Referring to FIG. 5, after formation of the non-magnetic layers 16, the resist masks R are brought into contact with a resist removal liquid to remove the resist masks R from the storage surface 15a of each storage layer 15 (resist removal step). An organic solvent that dissolves the resist masks R, makes the storage layers 15 and non-magnetic layers 16 insoluble, and maintains the magnetic characteristics of the storage layers 15 and non-magnetic layers 16 may be used as the resist removal liquid. Specifically, in the resist removal step, the substrate 11 with the resist masks R is immersed in the resist removal liquid to remove the resist masks R from the storage surface 15a of each storage layer 15 and remove the non-magnetic layers 16 deposited on the resist masks R. This forms the non-magnetic layers 16 in only the pits H. That is, the non-magnetic surfaces 16a and the storage surfaces 15a form a flat surface having a uniform level.

After removal of the resist masks R, the protection layer 17 and the lubricant layer 18 are laminated onto the surface of the substrate 11 (the storage surface 15a and the non-magnetic surface 16a, refer to FIG. 1). More specifically, for example, CVD is performed using hydrocarbon gas to laminate a diamond-like carbon layer (DLC layer: protection layer 17) onto the upper side of the storage layers 15 and the non-magnetic layers 16. This forms the magnetic disk 10, in which the surface 18a of the lubricant layer 18 has a high level of flatness.

### Second Embodiment

A second embodiment of a magnetic disk 10 according to the present invention will now be discussed with reference to the drawings. FIGS. 6 to 9 are diagrams illustrating the processes that are performed in a method for manufacturing the magnetic disk 10. The manufacturing processes subsequent to the non-magnetic layer formation step (FIG. 4) in the first embodiment are changed.

Referring to FIG. 6, after the pit formation step (FIG. 3) ends, sputter grains SP2 of a non-magnetic material are deposited onto the entire substrate 11 (non-magnetic layer formation step). Then, anisotropic sputtering is performed to form the non-magnetic layers 16 in the pits H and on the resist masks R.

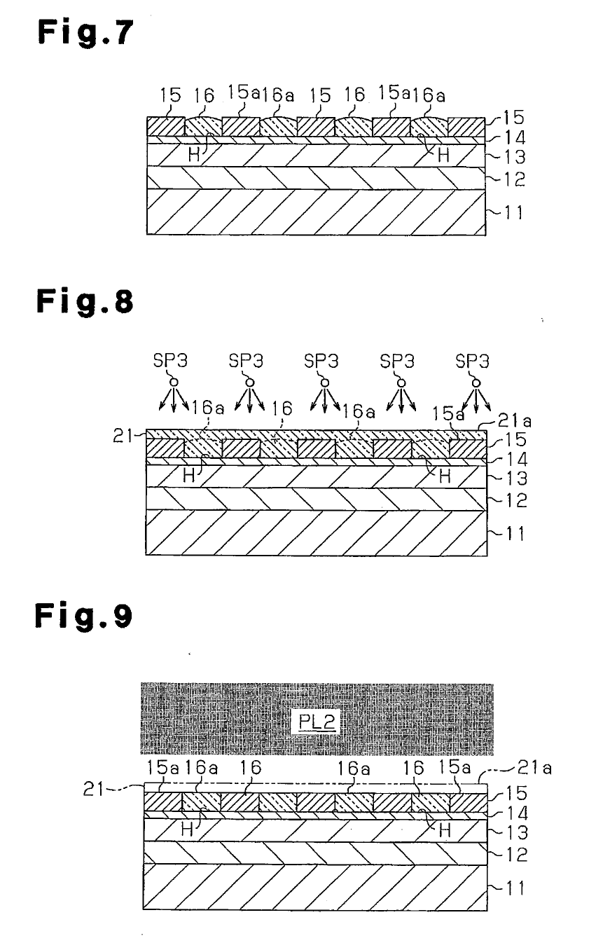

Referring to FIG. 7, after formation of the non-magnetic layers 16, in the same manner as the first embodiment, the resist masks R are brought into contact with a resist removal liquid to remove the resist masks R from the storage surface 15a of each storage layer 15 and remove the non-magnetic layers 16 deposited on the resist masks R (resist removal step). This forms the non-magnetic layers 16 in only the pits H.

Referring to FIG. 8, after removal of the resist masks R, isotropic sputtering is performed on the entire surface of the substrate 11 (the storage surfaces 15a and non-magnetic surfaces 16a) to deposit sputter grains SP3 of non-magnetic material. That is, a sacrificial layer 21 having a flat surface (sacrificial surface 21a) extending throughout the entire substrate 11 is formed on the storage surfaces 15a and the non-magnetic surfaces 16a. Isotropic sputtering refers to sputtering in which sputter grains strike the substrate from all directions and not just in the normal direction of the substrate (sacrificial layer formation step).

As a result, the sputter grains SP3 strike the substrate from all directions. This deposits the sputter grains SP3 so as to eliminate steps produced between the storage surfaces 15a and the non-magnetic surfaces 16a. Thus, a further flat sacrificial surface 21a is formed on the entire substrate 11. Further, at a timing at which the sacrificial layer 21 compensates for steps between the storage surfaces 15a and the non-magnetic surfaces 16a, the formation of the sacrificial layer 21 is ended. This minimizes the thickness of the sacrificial layer 21 and minimizes the time required to form the sacrificial layer 21.

Referring to FIG. 9, after forming the sacrificial layer 21, the entire substrate 11 is exposed to reactive plasma PL2 and the entire sacrificial layer 21 is etched at a uniform etching speed until the storage surfaces 15a become exposed (sacrificial layer removal step). A halogen gas, such as C₄F₈ or CF₄, a gas mixture of the halogen gas and Ar or N₂, or the like may be used as etching gas.

The sacrificial surface 21a of the sacrificial layer 21 is a flat surface. Thus, when the entire sacrificial layer 21 is sequentially etched and the storage surfaces 15a become exposed, flat non-magnetic surfaces 16a, which are continuous to the storage surfaces 15a, are formed in the regions corresponding to the pits H. As a result, when reactive ion etching (RIE) of the sacrificial layer 21 ends, the flat non-magnetic surfaces 16a will be formed flush with the storage surfaces 15a on the surface of the substrate 11.

After etching the sacrificial layer 21, the entire substrate 11 may be exposed to hydrogen plasma, which includes active hydrogen species (hydrogen ions and hydrogen radicals). This reduces the halogen active species collected on the storage layers 15 and the non-magnetic layers 16 with the hydrogen active species. Thus, corrosion (after corrosion) of the pattern of the storage layers 15 is avoided, and adhesion of the storage layers 15 and the protection layers 17 and adhesion of the non-magnetic layers 16 and the protection layer 17 are ensured.

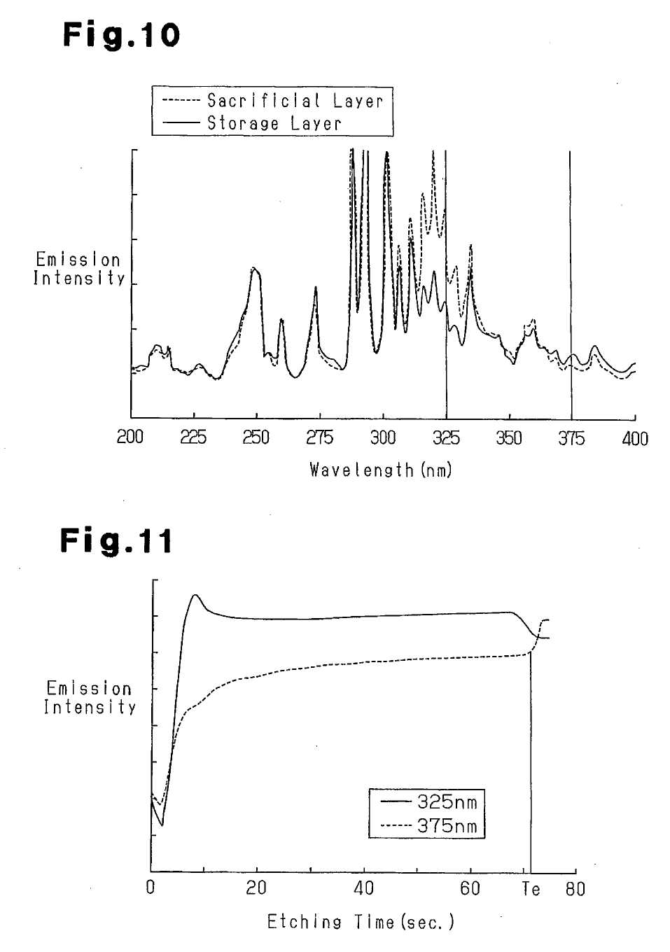

The timing at which RIE of the sacrificial layer 21 ends may be determined based on the light emitting intensity. FIG. 10 shows the emission intensity spectrum of light obtained when performing RIE on only the sacrificial layer 21. FIG. 11 shows changes as time elapses in the emission intensity of the lights for 325 nm and 375 nm in the sacrificial layer removal step

Referring to FIG. 10, the emission intensity of the light obtained through RIE of only the storage layers 15 and the emission intensity of light obtained through RIE of only the sacrificial layer 21 are first measured. Then, based on these measurement results, the wavelength at which the emission light intensity is different between the light obtained from the storage layers 15 and the light obtained from the sacrificial layer 21 is determined (detected wavelength: in FIG. 10, 325 nm and 375 nm).

In FIG. 10, for light having a wavelength of 325 nm, the intensity of the light obtained from the sacrificial layer 21 (broken line) is greater than the intensity of the light obtained from the storage layers 15 (solid line). On the other hand, for light having a wavelength of 375 nm, the intensity of the light obtained from the storage layers 15 (solid line) is greater than the intensity of the light obtained from the sacrificial layer 21 (broken line). Thus, in the sacrificial layer removal step, when the storage surfaces 15a become exposed after sequentially etching the sacrificial layer 21, the removal of the sacrificial layer 21 drastically decreases the intensity of the light of 325 nm, and the exposure of the storage surfaces 15a drastically increases the intensity of the light of 375 nm. That is, as shown in FIG. 11, based on the emission intensity of the lights of 325 nm and 375 nm obtained through RIE, as shown in FIG. 11, the time at which the intensity of the light of 325 nm drastically decreases and the intensity of the light of 375 nm drastically increases (termination time Te in FIG. 11) may be determined as the termination point for RIE. This ensures that excessive etching of the storage layers 15 is avoided. As a result, the storage surfaces 15a and the non-magnetic surfaces 16a may be formed into a flat surface with a higher recurrence.

After etching the sacrificial layer 21, the protection layer 17 and the lubricant layer 18 are sequentially laminated onto the surface of the substrate 11 (the storage surfaces 15a and the non-magnetic surfaces 16a). This compensates for the steps produced between the storage layers 15 and the non-magnetic layers 16 and forms the magnetic disk 10 with a higher level of flatness.

### Example 1

Example 1 of the first embodiment will now be discussed.

First, a circular glass-disk substrate having a diameter of 62.5 mm was loaded as the substrate 11 into a sputter apparatus.

Next, referring to FIG. 2, a CoTa target was used to obtain a CoTa layer having a thickness of 200 nm as the underlying layer 12. Further, a CoTaZr target was used to obtain a CoTaZr layer having a thickness of 500 nm as the soft magnetic layer 13. A Ru target was used to obtain a Ru layer having a thickness of 5 nm as the orientation layer 14. Then, a target mainly composed of CoCrPt and including SiO₂ was used to form a CoCrPt—SiO₂ layer having a thickness of 20 nm as the storage layers 15.

After forming the storage layers 15, referring to FIG. 3, EB positive resist was spin-coated onto the storage layers 15, and EB lithography was performed to obtain the resist masks R in correspondence with the data tracks. Then, the substrate 11 including the resist masks R was loaded into an RIE apparatus and the substrate was entirely exposed to the reactive plasma PL1 by using a gas mixture of Cl₂ and Ar to obtain the pattern of the storage layers 15. After patterning the storage layers 15, the substrate 11 was entirely exposed to hydrogen plasma to perform a reduction treatment on the surfaces of the storage layers 15 and the orientation layer 14.

After patterning the storage layers 15, the substrate 11 with the resist masks R was loaded into the sputter apparatus, and the distance between the SiO₂ target and the substrate 11 was increased to 300 mm. Further, the pressure between the SiO₂ target and the substrate 11 was decreased to 7×10⁻³ Pa. As a result, the striking direction of the sputter grains SP1 was brought close to the normal direction of the substrate 11. In other words, scattering of the sputter grains SP1 was suppressed. Further, referring to FIG. 4, the SiO₂ target was sputtered and the sputter grains SP1 of SiO₂ were deposited in the pits H and on the resist masks R. More specifically, anisotropic sputtering was performed until the thickness of the non-magnetic layers 16 deposited in the pits H became generally the same as the thickness of the storage layers 15 (depth of the pits H). This obtained the non-magnetic surfaces 16a, which were continuous with the storage surfaces 15a.

After forming the non-magnetic layers 16, the substrate 11 with the resist masks R were immersed in a resist removal liquid to remove the resist masks R and the non-magnetic layers 16 deposited on the resist masks R as shown in FIG. 5. This obtained a flat surface formed by the storage surfaces 15a and the non-magnetic surfaces 16a on the substrate 11. In this state, the maximum step on the surface of the substrate 11 (the storage surfaces 15a and the non-magnetic surfaces 16a) was measured. The maximum step in example 1 was 3 nm or less. Thus, the distance between the magnetic disk 10 and the magnetic head was controlled to be on the order of nanometers.

Finally, the protection layer 17 and the lubricant layer 18 were laminated on the surface of the substrate 11 (the storage surfaces 15a and the non-magnetic surfaces 16a), and the magnetic disk 10 was obtained with a high level of flatness.

### Example 2

Next, example 2 of the second embodiment will be discussed.

First, in the same manner as example 1, a circular glass-disk substrate having a diameter of 62.5 mm was loaded as the substrate 11 into the sputter apparatus, and the underlying layer 12, the soft magnetic layer 13, the orientation layer 14, and the storage layers 15 were obtained. Then, in the same manner as example 1, the resist masks R were formed on the storage layers 15, and RIE was performed using the resist masks R as a mask to obtain the pattern of the storage layers 15. Further, the substrate 11 was entirely exposed to hydrogen plasma to perform a reduction treatment on the surfaces of the storage layers 15 and the orientation layer 14.

After patterning the storage layer 15, the substrate 11 with the resist masks R was loaded into the sputter apparatus. Then, referring to FIG. 6, anisotropic sputtering was performed using the SiO₂ target to deposit the sputter grains SP2 of SiO₂ in the pits H and on the resist masks R.

After forming the non-magnetic layers 16, the substrate 11 with the resist masks R were immersed in a resist removal liquid to remove the resist masks R and the non-magnetic layers 16 deposited on the resist masks R as shown in FIG. 7. This obtained the non-magnetic surfaces 16a only in the pits H.

After removing the resist mask R, the substrate 11 was loaded into the sputter apparatus, and the distance between the SiO₂ target and the substrate 11 was set to 70 mm, which is sufficiently shorter than that for the anisotropic sputtering. Further, the pressure between the SiO₂ target and the substrate 11 was set to 1.0 Pa, which is sufficiently higher than that for the anisotropic sputtering. As a result, the striking direction of the sputter grains SP3 was inclined from the normal direction of the substrate 11. In other words, scattering of the sputter grains SP3 was enhanced. Further, referring to FIG. 8, the sputter grains SP3 of SiO₂ were deposited on the storage surfaces 15a and the non-magnetic surfaces 16a to form the sacrificial layer 21 with a thickness of 10 nm. That is, the sacrificial surface 21a, which is flat and compensates for the steps of the storage surfaces 15a and the non-magnetic surfaces 16a, was obtained.

After forming the sacrificial surface 21a, the substrate 11 is loaded into the RIE apparatus, and the entire surface of the substrate 11 was exposed to the reactive plasma PL2 to etch the sacrificial layer 21 until the termination time Te. Further, after etching the sacrificial layer 21, the substrate 11 was entirely exposed to hydrogen plasma to perform a reduction treatment on the storage surfaces 15a of the storage layer 15 and the non-magnetic surfaces 16a of the non-magnetic layers 16. A gas mixture of C₄F₈ and Ar or a gas mixture of CF₄ and Ar were used as the etching gas for the reactive plasma PL2. High-frequency power of 800 W was supplied to an antenna coil serving as a plasma source, and a bias high-frequency power was supplied to a substrate electrode serving as a self-bias voltage source. The chamber pressure was set at 0.5 Pa.

The RIE conditions described above avoid excessive etching of the storage layers 15. As a result, the non-magnetic surfaces 16a, which is flat and flush with the storage surfaces 15a, were obtained on the surface of the substrate 11. In this state, the maximum step on the surface of the substrate 11 (the storage surfaces 15a and the non-magnetic surfaces 16a) was measured. The maximum step in example 2 was 1 nm or less. Thus, the distance between the magnetic disk 10 and the magnetic head was sufficiently controlled to be on the order of nanometers.

Finally, the protection layer 17 and the lubricant layer 18 were laminated on the surface of the substrate 11 (the storage surfaces 15a and the non-magnetic surfaces 16a), and the magnetic disk 10 was obtained with a high level of flatness.

The method for manufacturing the magnetic disk 10 in each of the above embodiments has the advantages described below.

(1) In the manufacturing method of the first embodiment, the resist masks R are used to form the pits H for the storage layers 15. Then, the non-magnetic layers 16 are formed in the pits H and on the resist masks R so that the thickness of the non-magnetic layers 16 in the pits H is generally the same as the thickness of the storage layers 15 (the depth of the pits H). Then, the resist masks R and the non-magnetic layers 16 formed on the resist masks R are removed from the storage surfaces 15a of the storage layers 15.

Accordingly, the non-magnetic layers 16 may selectively be formed in only the pits H. In addition, the thickness of the non-magnetic layers 16 formed in the pits H is generally the same as the depth of the pits H. As a result, the storage surfaces 15a of the storage layers 15 and the non-magnetic surfaces 16a of the non-magnetic layer 16 are formed as flat surfaces having a uniform level. This improves the flatness of the magnetic storage medium.

(2) In the manufacturing method of the first embodiment, anisotropic sputtering using non-magnetic material is performed on the entire surface of the substrate 11, which includes the pits H, to form the non-magnetic layers 16 in the pits H and on the resist mask R. Accordingly, the sputter grains SP1, which are anisotropic, may enter and proceed inward (in the depthwise direction) into the pits H. This forms the non-magnetic surfaces 16a with further flatness.

(3) In the manufacturing method of the second embodiment, after removing the resist masks R, the storage surfaces 15a of the storage layers 15 and the non-magnetic surfaces 16a of the non-magnetic layers 16 both undergo isotropic sputtering using non-magnetic material. This forms the sacrificial layer 21, which compensates for steps of the storage surfaces 15a and the non-magnetic surfaces 16a on the upper side of the storage layer 15 and the non-magnetic layer 16. In other words, the sacrificial surface 21a formed on the surface of the substrate 11 is flat. Next, the sacrificial layer 21 is exposed to reactive plasma PL2 having a uniform etching speed to etch the sacrificial layer 21 until the storage surface 15a of the storage layer 15 is exposed.

Accordingly, the common and flat sacrificial surface 21a is formed on the storage surfaces 15a and the non-magnetic surfaces 16a. Further, by uniformly exposing the sacrificial layer 21 until the storage surfaces 15a become exposed, the storage surfaces 15a and the non-magnetic surfaces 16a are further flatly formed. Accordingly, excessive etching of the storage surfaces 15a is avoided.

(4) In the manufacturing method of the second embodiment, when etching the sacrificial layer 21, the emission intensity of light having a predetermined wavelength is detected. Further, when the emission intensity of the light having the detection wavelength reaches the emission intensity of the light obtained by etching the storage layers 15, etching of the sacrificial layer is terminated. Accordingly, when exposing the storage layers 15, the etching of the sacrificial layer 21 is terminated. Thus, excessive etching of the storage layer 15 is avoided. This improves the flatness of the magnetic disk 10 and stabilizes the magnetic characteristics of the magnetic disk 10.

The manufacturing method of each of the above embodiments may be modified as described below.

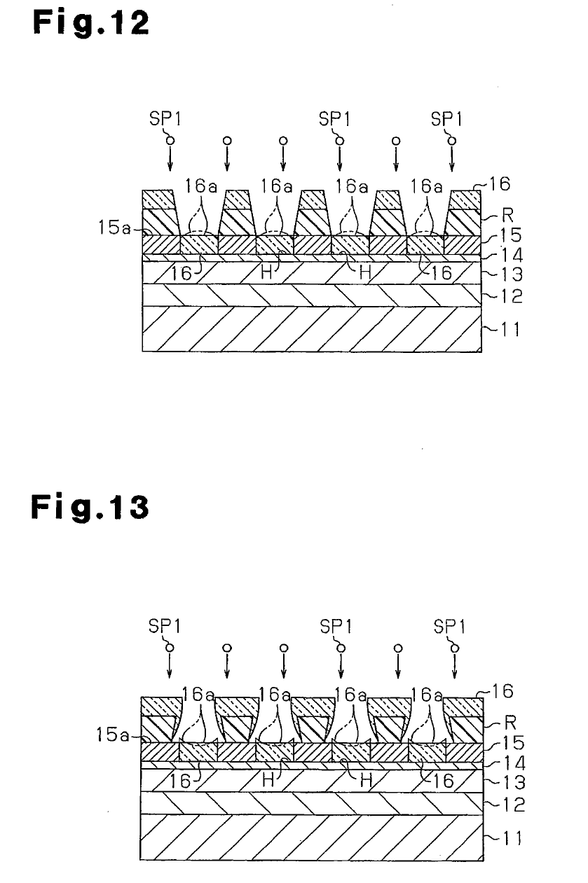

In each of the above embodiments, for example, as shown in FIG. 12, the side walls of the resist masks R may be tapered so as to enlarge openings between the resist masks R. This enables an increase in the striking angle of the sputter grains SP1 entering from the peripheries of the pits H. Thus, the depositing speed of non-magnetic material at the periphery of the pits H may be increased. For this reason, even if the non-magnetic surfaces 16a has an arcuate cross-section (double-dotted line in FIG. 12), the non-magnetic surface 16a may be further flattened (solid line in FIG. 12).

In each of the above embodiments, for example, as shown in FIG. 13, the side walls of the resist masks R may be inversely tapered so as to enlarge intervals between the bottom parts of the resist masks R. As a result, the sputter grains of non-magnetic material are inversely sputtered from the inner part of the pits H and collected on the bottom side wall of the resist masks R. This suppresses the narrowing of opening widths caused by inverse sputtering. Thus, even if the non-magnetic surfaces 16a have a dish-shaped cross-section (double-dotted line in FIG. 13), the non-magnetic surfaces 16a may further be flattened (solid line in FIG. 13).

In each of the above embodiments, for example, the storage layer 15 and the orientation layer 14 may both be etched using the resist masks R as a mask. In other words, the bottom surface of the pits H may be formed by the soft magnetic layers 13.

In the first embodiment, under the condition in which the distance between the target and substrate is greater than the diameter of the target, the pressure condition for anisotropic sputtering is not limited to 7×10⁻³ Pa as long as it is 1×10⁻¹ Pa or less.

1. A method for manufacturing a magnetic storage medium comprising the steps of:
forming a magnetic layer on a substrate;
forming a resist mask above the magnetic layer;
forming a pit in the magnetic layer using the resist mask;
forming a non-magnetic layer, which has a thickness that is in accordance with the depth of the pit, in the pit and above the resist mask; and
removing the non-magnetic layer deposited above the resist mask together with the resist mask from the magnetic layer.

2. The method for manufacturing a magnetic storage medium according to claim 1, wherein the step of forming a non-magnetic layer includes performing anisotropic sputtering using non-magnetic material to form the non-magnetic layer.

3. The method for manufacturing a magnetic storage medium according to claim 1, further comprising the steps of:
forming a sacrificial layer above the magnetic layer and the non-magnetic layer by performing isotropic sputtering using non-magnetic material; and
etching the sacrificial layer to expose the magnetic layer.

4. The method for manufacturing a magnetic storage medium according to claim 3, wherein the step of etching the sacrificial layer includes:
detecting the emission intensity of light having a predetermined wavelength during the etching; and
ending the etching of the sacrificial layer when the emission intensity of light having the predetermined wavelength reaches the emission intensity of light obtained by etching the magnetic layer.

5. The method for manufacturing a magnetic storage medium according to claim 1, wherein the step of forming a resist mask includes forming the resist mask above the magnetic layer so that the resist mask includes a tapered or inversely tapered side wall.

6. The method for manufacturing a magnetic storage medium according to claim 2, further comprising the steps of:
forming a sacrificial layer above the magnetic layer and the non-magnetic layer by performing isotropic sputtering using non-magnetic material; and
etching the sacrificial layer to expose the magnetic layer.

7. The method for manufacturing a magnetic storage medium according to claim 6, wherein the step of etching the sacrificial layer includes:
detecting the emission intensity of light having a predetermined wavelength during the etching; and
ending the etching of the sacrificial layer when the emission intensity of light having the predetermined wavelength reaches the emission intensity of light obtained by etching the magnetic layer.
